(19) United States
(12) Patent Application Publication
(10) Pub. No.: US 2010/0003509 A1
(43) Pub. Date: Jan. 7, 2010

(54) COATING METHOD FOR OPTICAL PLASTIC SUBSTRATES

(76) Inventors: Frank Breme, Hausen am Albis (CH); Alex Wetter, Thalwil (CH)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 12/449,336

(22) PCT Filed: Jan. 29, 2008
(86) PCT No.: PCT/CH2008/000028

§ 371 Date: Aug. 19, 2009

(30) Foreign Application Priority Data
Feb. 2, 2007 (CH) CH2007 00180/07

(51) Int. Cl. B32B 27/08; B05D 3/00; C08F 2/48; B05D 3/12; C23C 14/34; B05C 1/00; C23C 16/00

(52) U.S. Cl. 428/336; 427/393.5; 427/508; 427/322; 428/522; 204/192.12; 118/641; 204/298.02; 118/722

(57) ABSTRACT

In the method according to the invention for coating a plastic substrate with a transition layer, which particularly enables an improved bond of the optical functional layer system arranged above said transition layer to the plastic substrate lying underneath said transition layer, a polymerizable liquid is applied to a substrate surface of the plastic substrate to be coated, and said liquid is polymerized at that location, by irradiation with ultraviolet light, into a bonding agent which forms the transition layer. For this process, the plastic substrate passes consecutively through a high-pressure cleaning device (24), a spin-coating device (26), a UV-irradiation device (28), and a coating device (32) for applying the optical functional layer system.

The present invention relates to a method for coating optical plastic substrates according to the preamble of claim 1, to a device according to claim 13 for carrying out the method, and to a coating according to claim 17 produced by the method.

Optical coatings, for example for glare suppression or mirroring, optical filters and other treatments, are preferably produced by vacuum coating methods, which include inter alia vapor deposition (VD), chemical vapor deposition (CVD) and sputtering (physical vapor deposition, PVD). With the aid of these coating methods, inorganic layers with “ceramic” properties are typically applied onto substrates, for example glass, plastic or minerals.

These layers often bond only unsatisfactorily to plastic substrates, and owing to their mechanical and/or thermal properties they are also only limitedly compatible with the properties of these substrates. Owing to their low weight and their comparatively low production costs, the use of plastic substrates is of increasing importance for spectacles and watch glasses. Because of the mechanical and thermal stresses encountered in these fields of use, stringent requirements are placed on the required glare suppression (antireflection) and/or scratch-proofing layers in respect of their strength and optical quality. Even in the event of very minor deformations or temperature changes, for instance, reduced bonding and sometimes detachment of the coating may occur owing to the different material properties of the plastic substrate and the coating.

Conventionally, the problem of compatibility in the material properties of the plastic substrate and the coating are resolved either by applying hard varnishes or organic transition layers using wet chemical methods or by incorporating organic precursors during the coating with vacuum coating methods.

A method belonging to the latter group of methods is described, for example, in EP-A-1 655 385. Here, in order to form a transition layer during a sputtering process, organic precursors are fed in a controlled way into the vacuum chamber enclosing the substrate. These organic precursors are jointly incorporated into SiOₓ/SiN_{y} layers when they are being applied by sputtering. The elasticity of the transition layer can be adapted by means of the concentration of the precursors introduced, and the risk of detachment of the generally very brittle inorganic layer system subsequently applied is reduced.

A method belonging to the former group of methods is disclosed in DE-102005059485. In the method described therein, a liquid primer layer which contains a polymer solution is initially applied onto the plastic substrate. This primer layer is set by a subsequent drying process, before optical functional layers are then applied onto it by using a plasma.

Problems which are found in the group of wet chemical methods are in particular the relatively long time taken for drying or setting the primer or varnish layers. Besides the long cycle times which this entails for the production of coatings, relatively large amounts of manual work and concomitant high production costs, this also increases the risk that optical perturbations will be formed by incorporation of impurities.

Owing to the different refractive indices of the applied varnishes and plastic substrates, undesired optical interference phenomena such as the known Newton's rings may occur. Such intensity variations in the transmission as well as reflection of light can have a perturbing effect. Since the varnish layers have a relatively large thickness of the order of a few micrometers, it is very difficult to suppress these undesired phenomena by means of matching the functional layer systems applied on top. Such suppression is also hampered by the fact that the varnishes are only available, or economically viably producible, with a limited selection of refractive indices.

Furthermore the bonding (adhesion) of varnish layers, which generally have a high hardness, onto high-index plastic substrates such as MR7, MR8 or MR10 fundamentally entails problems. Even very minor material differences of the plastic substrates, which are unavoidable in the scope of the normal production processes, can lead to reduced bonding of the varnish layers.

It is therefore an object of the invention to provide a method, and a device for carrying out the method, which respectively make it possible to produce transition layers having improved bonding properties within short cycle times and therefore as economically as possible.

This object is achieved by the method according to the invention as claimed in claim 1, a device as claimed in claim 13 for carrying out this method, and a coating as claimed in claim 17 produced by the method according to the invention. Particularly preferred embodiments are provided with the features mentioned in the dependent claims.

In the method according to the invention for coating a plastic substrate, a transition layer, which is used for improved bonding of subsequently applied optical layers onto the plastic substrate, is produced from a bonding agent. The bonding agent is formed from a polymerizable liquid. To this end the polymerizable liquid is applied onto the plastic substrate's substrate surface to be coated, where it is subsequently polymerized to form the bonding agent.

The polymerization process can be carried out within a few seconds by using suitable light sources, so that the cycle times for producing the transition layers by the method according to the invention are shortened substantially in comparison with the known conventional methods. The shorter cycle times in turn permit a higher degree of automation in the overall production of the coating, and consequently lead to a reduction of the production costs together with an increased optical quality of the transition layers. It is furthermore possible to adapt the polymerizable liquid and its polymerization conditions, for example the intensity, spectrum and exposure time of the light, to the specific material properties of the plastic substrates and thereby achieve improved bonding of the transition layer onto the plastic substrate.

A corresponding device for carrying out the method according to the invention successively contains a high-pressure cleaning instrument for cleaning the plastic substrate, a spin coating instrument for applying the polymerizable liquid, a UV irradiation instrument which is used to polymerize the polymerizable liquid and thereby form the transition layer, and a subsequent coating instrument for applying further layers, in particular optical functional layers.

Preferably, the transition layer can be applied with such a small thickness that undesired interference phenomena can be suppressed at least in a predetermined spectral range of the light by matching subsequently applied layers.

As already mentioned, the method according to the invention is particularly suitable for a high level of automation. This fact is exploited in terms of device technology inter alia by loading the individual instruments automatically. Computer-assisted measurement, control and regulating units may be used for monitoring and optimized control of the manufacturing process.

A particularly preferred embodiment of the method according to the invention and a device for carrying out the method will be described in more detail below with the aid of the drawing in which, purely schematically:

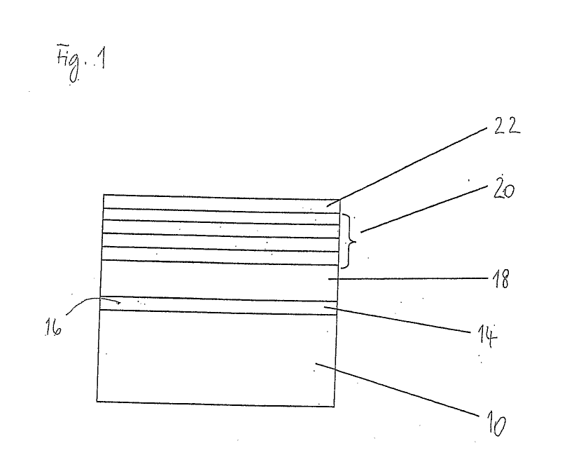

FIG. 1 shows a sectional representation of an example of the coated plastic substrate, which is equipped by the method according to the invention with a transition layer formed by a bonding agent;

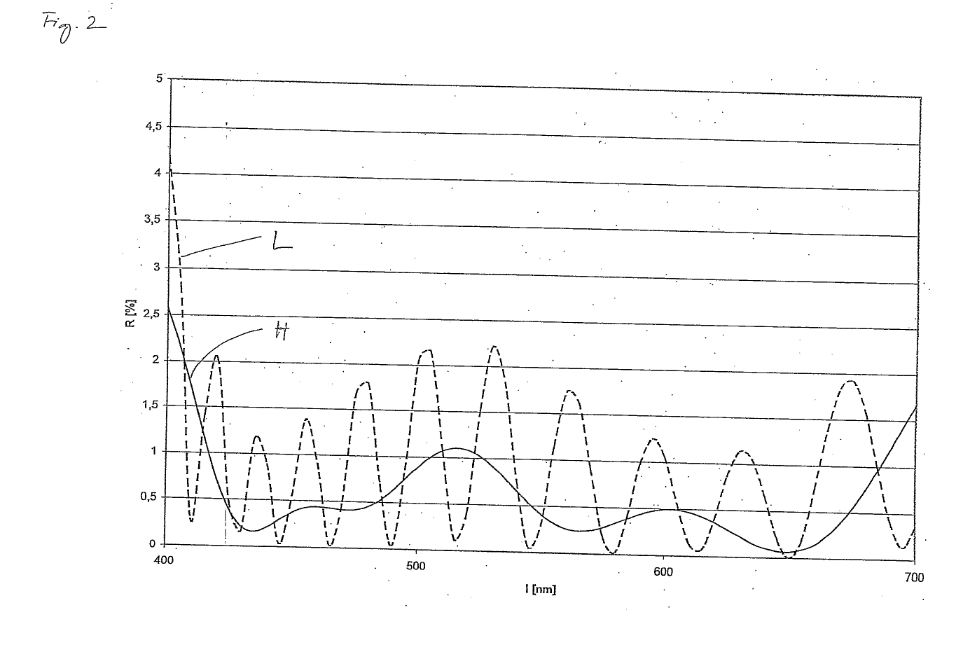

FIGS. 2-4 show diagrams in which the optical reflectivity is represented as a function of the wavelength of the light passing through the coated plastic substrates in the case of antireflection coatings, which are applied on the one hand onto a transition layer formed by the bonding agent (continuous lines H, H1, H2) and on the other hand by a conventional varnish layer (dashed lines L, L1, L2); and

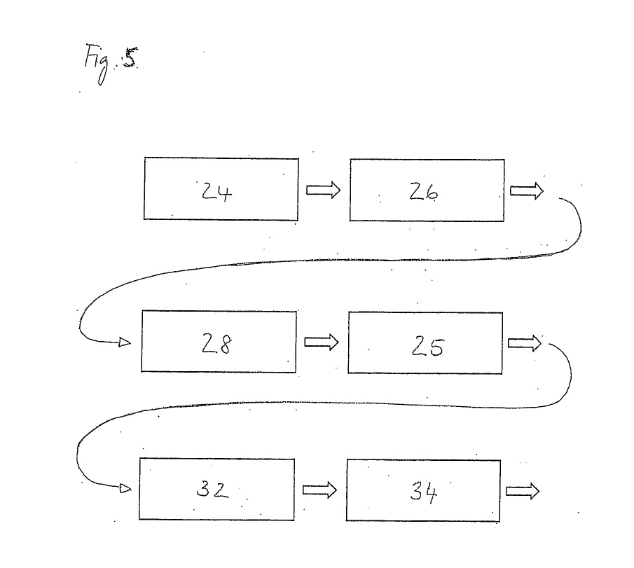

FIG. 5 shows a block diagram of the instruments through which the plastic substrate passes in the direction of the arrows when carrying out the method according to the invention.

FIG. 1 represents a plastic substrate 10 and, applied thereon, a functional coating which has been produced by the method according to the invention. A transition layer 14 is applied directly on a substrate surface 12 of the plastic substrate 10. The transition layer 14 is formed by a bonding agent 16 and has a thickness of between 10 nm and 5000 nm, preferably between 40 and 200 nm, particularly preferably between 60 nm and 100 nm, and in the embodiment shown about 100 nm. In a spin coating method for producing the transition layer 14, for example, this layer thickness may be achieved by adjusting the rotation speed, the rotation time and the solvent concentration or solids content of the solvent-based bonding agent 16. In the transition layer 14, the bonding agent 16 fulfils a function of bridging to a hard layer 18 arranged above, by the bonding agent 16 having much better adhesion properties on the plastic substrate side than the hard layer 18 and also presenting improved compatibility with the material properties, in particular the mechanical and thermal properties of the hard layer 18. Thus, detachment of the generally very brittle hard layer 18 is prevented by a high elasticity and the resulting ability of the transition layer 14 to adapt to mechanically or thermally induced shape changes.

In the examples shown, the hard layer 18 consists predominantly of SiO₂ applied by means of sputtering technology, into which for example elastic components may be incorporated by introducing organic precursors during the production process. The thickness of the hard layer 18 is between 100 nm and 3000 nm, in the example shown about 800 nm. The thickness to be used for the hard layer 18 depends strongly on the specific material composition of the plastic substrate 10. As a general rule, a greater thickness of the hard layer 18 will lead to improved scratch resistance.

Above the hard layer 18, on the opposite side from the sandwiched transition layer 14, the optical functional layer 20 per se is arranged which is used for glare suppression in the example shown. The optical functional layer 20 consists, starting from the hard layer 18, of a 30 nm thick layer of Si₃N₄, a 25 nm thick layer of SiO₂, a 65 nm thick layer of Si₃N₄ and again 95 nm thick layer of SiO₂ lying above. As already mentioned, the optical functional layer system 20 is specified merely by way of example and may correspondingly be adapted both in its dimensions and in its material composition according to the desired optical properties.

On the other side of the optical functional layer 20 from the hard layer 18, a hydrophobic cover layer 22 is arranged which is used to repel dirt.

In the diagram of FIG. 2, for an optical functional layer 20 in the form of an antireflection layer the optical reflectivity R (in percent) is represented as a function of the wavelength l (in nm) of the light passing through the coated plastic substrate 10. The two lines H, L shown relate to the same types of plastic substrates MR7 with a refractive index of 1.67 and an antireflection layer system consisting of SiN (refractive index 1.97; layer thickness 29 nm), SiO₂ (refractive index 1.47; layer thickness 26 nm), SiN (refractive index 1.97; layer thickness 64 nm) and SiO₂ (refractive index 1.47; layer thickness 94 nm).

The solid line H results from a reflectivity measurement of a plastic substrate 10 coated by using the method according to the invention, in which first a 60 nm thick transition layer 14 (refractive index 1.56) comprising the bonding agent 16 and above this, to suppress undesired interference phenomena, a first matching layer of SiO₂ (layer thickness 15 nm; refractive index 1.47) and a second matching layer of SiN (layer thickness 2 nm; refractive index 1.97) have been applied onto the plastic substrate 10. Above these matching layers, before the antireflection layer per se, there is also a hard layer 18 of SiO₂ (layer thickness 740 nm; refractive index 1.47).

In order to determine the dashed line L, a plastic substrate 10 on which a 3000 nm thick varnish layer (refractive index 1.47) was applied by a conventional coating method, below the same antireflection layer as specified above, was measured.

As may be seen from the profile of the lines H, L in FIG. 2, the reflectivity R of the plastic substrate 10 coated according to the invention (line H) oscillates much less than the reflectivity R of the plastic substrate 10 provided with the varnish layer (line L). This demonstrates the successful suppression of undesired interference phenomena, manifested as oscillations in the reflectivity R, with the aid of the matching layers.

As an alternative, in another exemplary embodiment, the hard layer 18 may also be applied by a so-called UV spin coating method. Possible UV, varnishes forming the hard layer 18 in this case are, for example, varnishes with the brand name HT 850 and SHC 178. The refractive indices of the bonding agent 16 and of the hard layer 18 formed by the UV varnish are advantageously adapted to one another so as to minimize undesired interference (for example so-called Newton's rings). This is achieved by selecting the refractive index of the bonding agent 16 to be greater than that of the hard layer 18. The refractive index n of the bonding agent 16 is also less than that of the plastic substrate 10, so that n(substrate)>n(bonding agent)>n(hard layer). Furthermore, the layer thickness of the bonding agent 16 should be less than 200 nm. The thickness of the hard layer 18 is greater than that of the bonding agent 16, and lies in particular between 500 nm and 5000 nm.

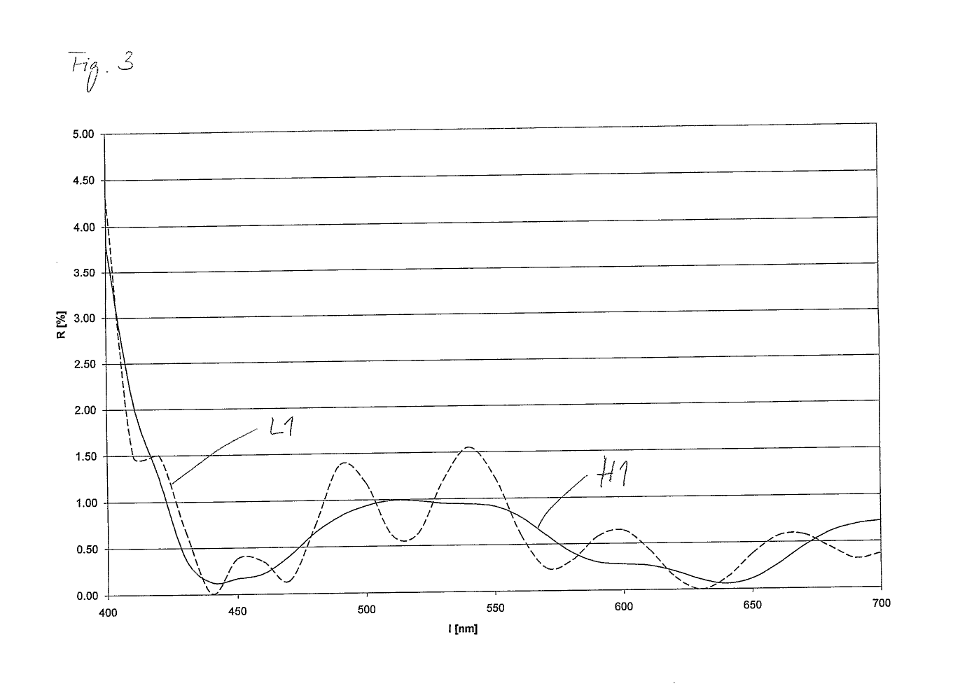

In FIG. 3 of this exemplary embodiment, the optical reflectivity R (in percent) is represented as a function of the wavelength l (in nm) of the light passing through the coated plastic substrate 10. The two lines H1, L1 shown relate to the same types of plastic substrates MR8 with a refractive index of 1.6.

The solid line H1 results from a reflectivity measurement of a plastic substrate 10 coated by using the method according to the invention, in which first an 80 nm thick transition layer (refractive index 1.55) comprising the bonding agent 16, above this a hard layer 18 (for example of the UV varnish SHC 178 from Lens Technology International, La Mirada, Calif. 90638, USA) with a refractive index of 1.51 and a thickness of 1500 nm, and subsequently five sputtered layers consisting of SiO₂ (refractive index 1.47; layer thickness of 40 nm), Si₃N₄ (refractive index 1.97; layer thickness 33 nm), SiO₂ (refractive index 1.47; layer thickness of 22 nm), Si₃N₄ (refractive index 1.97; layer thickness 66 nm) and SiO₂ (refractive index 1.47; layer thickness of 95 nm) have been applied onto the plastic substrate 10.

In order to determine the dashed line L1, a plastic substrate 10 on which a 3000 nm thick varnish layer (refractive index 1.47) was applied by a conventional coating method, below the same antireflection layer as specified above, was measured.

As may be seen from the profile of the lines H1, L1 in FIG. 3, the reflectivity R of the plastic substrate 10 coated according to the invention (line H1) oscillates much less than the reflectivity R of the reference plastic substrate 10 provided with the varnish layer (line L1). This demonstrates the successful suppression of undesired interference phenomena, manifested as oscillations in the reflectivity R, with the aid of the specifically adapted and mutually matched layers of bonding agent 16, hard layer 18 and sputtered layers.

It is known that in order to achieve the desired optical properties for the plastic substrate 10 to be coated, the layer thicknesses and layer arrangements of the matching layers and subsequent functional layers may be computationally determined and optimized before application, while taking the refractive indices into account. In practice, this proves feasible and extremely advantageous for the coatings produced by the method according to the invention owing to the small layer thickness of the transition layer 14, preferably less than 300 nm. When using conventional varnish layers, however, such suppression of undesired interference phenomena is limited by the thickness of the varnish layer and is virtually impossible or unrealistic.

When using varnishes, suppression of perturbing interference phenomena is also hampered because the varnishes are only available in a limited selection of refractive indices. Particularly when a refractive index of 1.67, which corresponds to that of an MR7 plastic subject material, or higher, refractive index matching to the substrate material can be carried out only with very expensive varnishes or not at all. In contrast to this, in the case of coating by the method according to the invention, instead of applying bonding agents 16 with different refractive indices the thickness of the transition layer 14 or advantageously the thickness of the layers subsequently applied, in particular the matching layers or the layers of the optical functional system 20, may be adapted accordingly. In respect of this aspect, the method according to the invention for producing such a coating is particularly cost-efficient, time-saving and precise, and permits coatings with high optical quality.

It may be seen both from the diagram in FIG. 2 and the diagram in FIG. 3 that a reflectivity R of the solid line H, averaged over corresponding spectral ranges (for example from 550 nm to 650 nm), has a value lower than that of the dashed line L. This behavior, achieved for the line H by means of the method according to the invention, is particularly advantageous specifically for antireflection coatings.

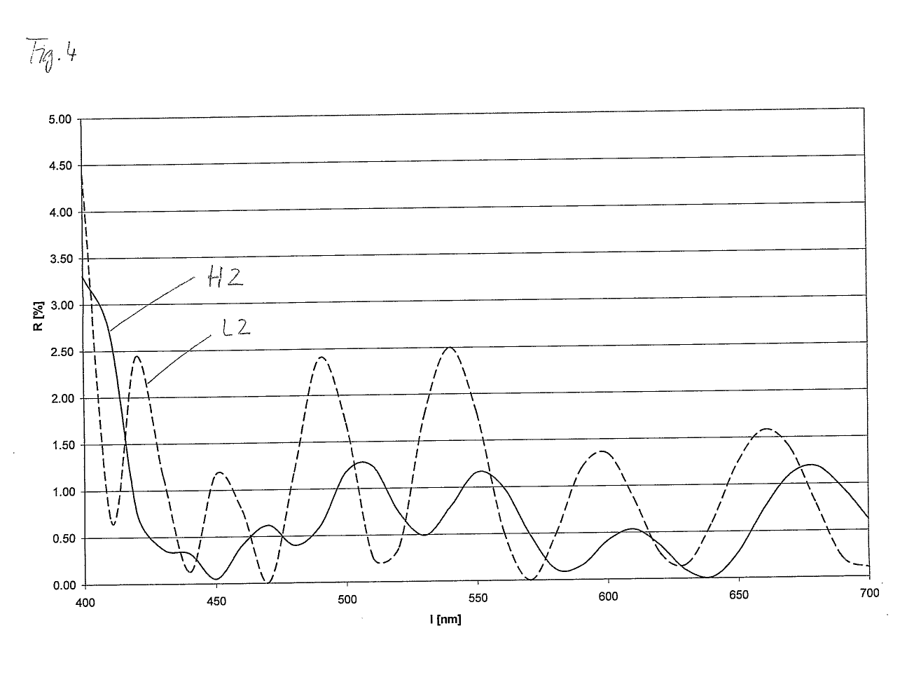

FIG. 4 represents another exemplary embodiment. For an optical functional layer system 20 in the form of an antireflection layer, the optical reflectivity R (in percent) is represented as a function of the wavelength l (in nm) of the light passing through the coated plastic substrate 10. In the embodiment shown, for plastic substrates 10 with a refractive index of 1.67 or more, sputtered layers are introduced for refractive index matching between the bonding agent 16 and the hard layer 18, the number, type and thickness of the sputtered layers respectively being adapted to the combination of plastic substrate 10, bonding agent 16 and hard layer 18.

A possible example of such an embodiment is a plastic substrate 18 with a refractive index of 1.74, onto which first a bonding agent 16 with a refractive index of 1.55 and a thickness of 40 nm, subsequently two first sputtered layers applied by means of sputtering and consisting of SiO₂ (refractive index 1.47; layer thickness 5 nm) and Si₃N₄ (refractive index 1.97; layer thickness 6 nm), subsequently again a hard layer 18 of a UV varnish (for example of the UV varnish SHC 178 from Lens Technology International, La Mirada, Calif. 90638, USA) with a refractive index of 1.51 and a thickness of 1500 nm, and finally also five further second sputtered layers applied by means of sputtering and consisting of SiO₂ (refractive index 1.47; layer thickness 40 nm), Si₃N₄ (refractive index 1.97; layer thickness 33 nm), SiO₂ (refractive index 1.47; layer thickness 22 nm), Si₃N₄ (refractive index 1.97; layer thickness 66 nm) and SiO₂ (refractive index 1.47; layer thickness 95 nm) are applied.

In order to determine the dashed line L2, an identical plastic substrate 10 on which no bonding agent 16 and no sputtered layers were applied before the hard layer 18, in this case the UV varnish layer, was measured.

As may be seen from the profile of the lines H2, L2 in FIG. 4, here again the reflectivity R of the plastic substrate 10 coated according to the invention (line H2) oscillates much less than the reflectivity R of the reference substrate (line L2). This demonstrates the successful suppression of undesired interference phenomena, manifested as oscillations in the reflectivity R, with the aid of the adapted combination of the layer of bonding agent 16, the first sputtered layers, the hard layer 18 and the second sputtered layers.

The method according to the invention will be explained in more detail below with the aid of the block diagram represented in FIG. 5 with arrows pointing in the process direction. The plastic substrate 10 to be processed, for example a spectacle lens formed from the plastic MR8, has already been hardened by means of a dipping varnish in mass production and modified on its concave rear side in individual processing by milling, grinding, polishing etc. so that it correctly exerts the optical effect required of the spectacle lens.

In a first method step, possibly adhering contaminants are removed from this plastic substrate 10 by means of a high-pressure cleaning instrument 24, in particular a high-pressure vapor cleaning instrument.

Subsequently, in a spin coating instrument 26, from 0.1 ml to 5 ml, preferably 1 ml of a polymerizable liquid for forming the bonding agent, which constitutes the transition layer 14 is sprayed onto the concave, still to be coated rear side of the plastic substrate 10. By rotation about a rotation axis essentially oriented perpendicularly to the substrate surface 12 and preferably at least substantially extending through the center of mass of the plastic substrate 10, with a rotation speed of between 200 revolutions per minute and 2000 revolutions per minute, preferably 500 revolutions per minute for a time of about 10 seconds, the polymerizable liquid is distributed uniformly over the concave rear side.

Naturally, other methods instead of spin coating may also be used in order to generate a uniform layer of the polymerizable liquid on the plastic substrate 10, for example an immersion method.

In the embodiment described above, the polymerizable liquid for forming the bonding agent 16 is a liquid organic monomer, preferably based on acrylates or epoxides, for example the product P-201B from Lens Technology International, La Mirada, Calif. 90638, USA. The polymerizable liquid may preferably be polymerized by exposure to light, in particular ultraviolet (UV) light, i.e. light with substantial energy components in the ultraviolet part of its spectrum. By the polymerization to form the bonding agent 16, the polymerizable liquid is “hardened” and leads to strong adhesion of the macromolecules, generated by the polymerization, onto the underlying substrate surface 12 of the plastic substrate 10.

The polymerization by exposure to ultraviolet light is carried out in the UV exposure instrument 28, to which the plastic substrates are preferably delivered in an automated fashion by means of a transport instrument (not shown). The UV exposure device 28 has a UV source, preferably a UV lamp. The plastic substrate 10 coated with the polymerizable liquid is exposed to ultraviolet light for a time of from 0.1 s to 60 s, preferably about 10 s, with a light intensity of from 1 W/cm² to 200 W/cm², preferably 100 W/cm². These exposure parameters, like the other polymerization conditions overall, should naturally be adapted to the polymerizable liquid, the plastic substrate 10 in question and the desired properties of the transition layer 14.

In a next method step, the convex front side of the plastic substrate 10 coated with the transition layer 14, which inter alia may be contaminated by a holding mechanism in the spin coating instrument 26, is then cleaned by means of another high-pressure cleaning instrument 25, preferably a high-pressure vapor cleaning instrument. This method step is optional, and may if appropriate also be carried out at another time during the production method or be entirely omitted. Likewise optionally, the plastic substrate 10 may subsequently be dried in a water extraction instrument, for example in a continuous infrared oven.

The optical functional layer system 20 is then applied onto the transition layer 14, conditioned in this way, on the plastic substrate 10 in a coating instrument 32. In the coating instrument 32, the coating, for example to form the optical functional layer system 20 shown in FIG. 1, may be carried out by means of sputtering or CVD coating methods, in particular one of the methods disclosed in EP-A-1 275 751 or EP-A-1 655 385. The layer thicknesses of the individual layers of the optical functional layer system 20 may be adapted to the specific refractive index of the plastic substrate 10 or other functional or application requirements in order to impart optimal optical properties to the coating.

The coating is preferably carried out not only on the concave rear side provided with the transition layer 14, but likewise and optionally also simultaneously on the convex front side of the plastic substrate 10 which has been hardened for example by a dipping varnish.

Subsequently, the hydrophobic cover layer 22 described in conjunction with FIG. 1 is applied either in the coating instrument 32 or in a further coating instrument 34.

Owing to the relatively short cycle times for carrying out the method according to the invention, due in particular to the short time for polymerizing the transition layer 14, said method and the described device are suitable for full automation of the production process. The method which takes place in an automated form, preferably with computer assistance, is suitable in particular for coating plastic glasses for spectacles or timepieces, but also for optical elements of scientific instrument production, packaging technology or power technology.

1. A method for coating a plastic substrate comprising the steps of:
applying a polymerizable liquid onto a substrate surface of the plastic substrate and wherein the polymerizable liquid is polymerized there into a bonding agent which forms a transition layer for improved bonding of a layer or layer system applied over the transition layer.

2. The method as claimed in claim 1, wherein the polymerizable liquid is distributed uniformly over the substrate surface by means of a spin coating.

3. The method as claimed in claim 2, wherein during spin coating, from 0.5 ml to 5.0 ml of the polymerizable liquid for forming the bonding agent is applied onto the substrate surface and the plastic substrate is subsequently rotated with a rotation speed from 200 revolutions/min to 2000 revolutions/min about a rotation axis essentially oriented perpendicularly to the substrate surface.

4. The method as claimed in claim 1, wherein the polymerization of the polymerizable liquid to form the bonding agent is induced by light.

5. The method as claimed in claim 4, wherein the polymerization is carried out under ultraviolet (UV) light from a UV radiation source, with an exposure time of from 0.1 s to 60 s, with a light intensity of from 1 W/cm² to 20 W/cm².

6. The method as claimed in claim 1, wherein the layer thickness of the bonding agent (16) is from 10 nm to 5000 nm.

7. The method as claimed in claim 1, wherein undesired optical interference phenomena are suppressed by computationally predetermined adaptation of layer thickness of the layer system to be applied above the transition layer.

8. The method as claimed in claim 1, wherein the substrate surface to be coated is cleaned by means of high-pressure vapor cleaning before applying the transition layer.

9. The method as claimed in claim 1, wherein a hard layer is applied onto the transition layer.

10. The method as claimed in claim 9, wherein at least one sputtered layer is applied by means of sputtering, between transition layer of the bonding agent and the hard layer.

11. The method as claimed in claim 1, wherein the layer or layer system which is applied above the transition layer has an optical functional layer system with an antireflection layer used for glare suppression.

12. The method as claimed in claim 1, wherein the layer or layer system which is applied above the transition layer has a hydrophobic cover layer.

13. The method as claimed in claim 1, wherein the layer or layer system is applied above the transition layer (24) by means of sputtering, chemical vapor deposition (CVD), CVD-enhanced sputtering, or UV spin coating.

14. A device for carrying out the method as claimed in claim 1 which has a high-pressure cleaning instrument, a spin coating instrument, a UV irradiation instrument and a coating instrument, which are adapted for the plastic substrate to pass through in the order mentioned.

15. The device as claimed in claim 14, wherein the device is operated in an at least partially automated fashion.

16. The device as claimed in claim 14, wherein the coating instrument is adapted for coating by means of sputtering, chemical vapor deposition (CVD), or CVD-enhanced sputtering.

17. The device as claimed in claim 14, wherein the coating instrument or a further coating instrument belonging to the device is adapted to apply a hydrophobic cover layer.

18. A coating produced by a method as claimed in claim 1.

19. The coating as claimed in claim 18, wherein the transition layer as a layer thickness of less than 500 nm so that undesired optical interference phenomena can be suppressed by the layer system to be applied above the transition layer, with computationally optimized layer thicknesses.
